(19) United States
(12) Patent Application Publication
(10) Pub. No.: US 2016/0014933 A1
(43) Pub. Date: Jan. 14, 2016

(54) ELECTRONIC APPARATUS COOLING SYSTEM AND ELECTRONIC APPARATUS COOLING SYSTEM FABRICATION METHOD

(71) Applicant: NEC CORPORATION, Tokyo (JP)

(72) Inventors: Arihiro MATSUNAGA, Tokyo (JP); Minoru YOSHIKAWA, Tokyo (JP); Hitoshi SAKAMOTO, Tokyo (JP); Masaki CHIBA, Tokyo (JP); Akira SHOUJIGUCHI, Tokyo (JP); Kenichi INABA, Tokyo (JP)

(73) Assignee: NEC Corporation, Tokyo (JP)

(21) Appl. No.: 14/769,935

(22) PCT Filed: Feb. 19, 2014
(86) PCT No.: PCT/JP2014/000842

§ 371 Date: Aug. 24, 2015

(30) Foreign Application Priority Data
Feb. 26, 2013 (JP) 2013-035455

(51) Int. Cl. H05K 7/20; B23P 19/00

(52) U.S. Cl. CPC H05K 7/20818; B23P 19/00; H05K 7/20327; H05K 7/20318

(57) ABSTRACT

[Problem]

To provide an electronic apparatus cooling system having superior cooling characteristics and portability.

[Solution] A rack 2 is installed within a container 1. A heat receiving apparatus 3 is disposed on a lateral face of the rack 2, and receives heat emitted within the rack 2 by a liquid-phase cooling medium gasifying and becoming a gaseous-phase cooling medium. A gaseous-phase tube 6 is disposed extending in plumb direction, and transports the gaseous-phase cooling medium from the heat receiving apparatus 3. A heat radiating apparatus 4 is disposed above the rack 2 outside the container 1, and radiates the heat which the heat receiving apparatus 3 has received by cooling the gaseous-phase cooling medium flowing from the gaseous-phase tube 6, making said gaseous-phase cooling medium into the liquid-phase cooling medium. A liquid-phase tube 7 transports the liquid-phase cooling medium from the heat radiating apparatus 4 to the heat receiving apparatus 3. The gaseous-phase tube 6 further comprises a gaseous-phase tube bend part 6c whereat cooling medium droplets, which arise from the condensation of the gaseous phase cooling medium as a result of the gaseous-phase tube 6 being exposed to the environment external to the container 1, are collected.

### TECHNICAL FIELD

The present invention relates to an electronic apparatus cooling system and a fabrication method of the electronic apparatus cooling system.

### BACKGROUND ART

Recently, a great increase of information quantity has been expected along with development of information society. Due to the information increase, it becomes needed to install a plenty of electronic apparatus such as servers for information processing. However, it is difficult to rapidly increase the number of electronic apparatus installations owing to the installation space problem and the installation environment such as the problem concerning to an air conditioner or power supply.

Accordingly, a modular type data center has been proposed which comprises equipment which adjusts an operation environment of the air conditioner or the like together with a rack in which a plenty of servers and network devices are equipped. As the modular type data center, for example, a container type data center which uses the container as an outer wall of the data center has been proposed. By applying the container which meets the ISO (International Organization for Standardization) specification to the container type data center, existing container transportation equipment can be used. Therefore, it is very profitable from the view point of speed-up of the data center installation. Since the container type data center can be transported easily after assembling in a factory, the production capacity can be increased. In this way, since short time installation is possible and information processing throughput is increased in the container type data center, employment thereof is expected to increase hereafter.

However, it is difficult to keep a space enough to send cooling air from the air conditioner to each rack when the racks equipped with a large number of servers are installed in a small space of the ISO specification container. Therefore, a short return which inhales exhaust of the server occurs and each server cannot be cooled sufficiently. The problem that cooling electric power increases due to measures for the short return also occurs. Therefore, technologies which efficiently cool exhaust heat of the server and the network device is required.

As an endothermic technology for the exhaust heat of the server, the method is considered that water is drained into the heat exchanger provided on the rear door of the rack, the exhaust heat from the server is absorbed, and the cooling electric power is reduced (Patent Literature 1). Moreover, the structure is proposed which boils a cooling medium by installing a heat exchanger on a rear door and receiving the exhaust heat of the server with the cooling medium in the rear door, transports vapor which is generated by boiling to the external heat exchanger and removes the exhaust heat (Patent Literature 2). Besides, the structure is proposed that reduces the cooling electric power by transporting heat of a CPU in a server to the heat exchanger on the upper part of the rack and using a large heat radiating apparatus (Patent Literature 3). In addition, the cooling apparatus is also proposed which cools the electrical equipment in the flameproof container by naturally circulating the cooling medium and discharging the heat in the atmosphere (Patent Literature 4).

### CITATION LIST

### Patent Literature

[PTL 1] Japanese Patent Application Laid-Open No. 2010-72993

[PTL 2] Japanese Patent Application Laid-Open No. 2012-118781

[PTL 3] Japanese Patent Application Laid-Open No. 2012-177959

[PTL 4] Japanese Patent Application Laid-Open No. 2003-28549

### SUMMARY OF INVENTION

### Technical Problem

However, the inventor has found that the above-mentioned technologies have a problem described below. In the technology disclosed in Patent Literature 1, a large circulation pump for absorbing the heat by circulating liquid is needed. In addition, a large scale apparatus such as chiller which cools the transported heat is needed. Taking transportation convenience and a restricted installation space into account, it is disadvantageous for the container type data center.

The technology disclosed by the Patent Literature 2 transports heat without using a pump by using a boiling cooling medium and naturally circulating vapor which is generated when the cooling medium which has received the heat is boiled. However, since cold water supplied from the chiller or the like is needed, the equipment still becomes large in this case. Therefore, when this technology is applied to the container type data center, the transportation becomes difficult.

The technology disclosed by Patent Literature 3 can reduce the cooling electric power by installing the heat exchanger in each blade server CPU (Central Processing Unit) of the rack, and cooling with utilizing the large heat exchanger on the rack. However, since the heat exchanger is installed on the CPU, the blade server cannot be exchanged easily. In addition, in the container type data center, when the heat exchanger is installed outside the container, the tubes in which a cooling medium vaporized by the heat of CPU or the like passes exposes open air. Therefore, a flow of a vapored cooling medium is obstructed and the cooling performance declines since cooling medium condensation occurs easily and the condensed liquid-phase cooling medium descends in the tube. Patent Literature 4 has the similar problem that the flow of the vapored cooling medium is obstructed and the cooling performance declines since the condensed liquid-phase cooling medium descends in the tube.

The present invention is formed in view of the above-mentioned circumstances, and an object of the present invention is to provide an electronic apparatus cooling system with excellent cooling characteristics and portability.

### Solution to Problem

An electronic apparatus cooling system, which is one aspect of the present invention, includes a portable container with a space that can store an article therein, a storage container that installs an electronic apparatus that is installed inside the portable container, a heat receiving apparatus that is installed on a side of the storage container and receives heat that is generated inside the storage container as a liquid-phase cooling medium is evaporated to become a gaseous-phase cooling medium, a gaseous-phase cooling medium transportation means that is installed so as to extend in the vertical direction and transports the gaseous-phase cooling medium from the heat receiving apparatus, a heat radiating apparatus that is installed above the storage container outside the portable container, and radiates the heat that the heat receiving apparatus receives by cooling the gaseous-phase cooling medium that flows into from the gaseous-phase cooling medium transportation means to make the liquid-phase cooling medium, and a liquid-phase cooling medium transportation means that transports the liquid-phase cooling medium from the heat radiating apparatus to the heat receiving apparatus, wherein the gaseous-phase cooling medium transportation means includes a liquid droplet collecting means that collects a cooling medium liquid droplet that is generated when the gaseous-phase cooling medium transportation means is exposed to atmosphere outside the portable container and the gaseous-phase cooling medium is condensed.

A method of manufacturing an electronic apparatus cooling system, which is one aspect of the present invention, includes, installing a storage container having an electronic apparatus therein inside a portable container whose internal space is sealable, installing a heat receiving apparatus that receives heat that is generated inside the storage container as a liquid-phase cooling medium is evaporated to become a gaseous-phase cooling medium, on a side of the storage container,

installing a gaseous-phase cooling medium transportation means that transports the gaseous-phase cooling medium from the heat receiving apparatus so as to extend in the vertical direction, installing a heat radiating apparatus radiating the heat which the heat receiving apparatus receives by cooling the gaseous-phase cooling medium that flows in from the gaseous-phase cooling medium transportation means so as to generate the liquid-phase cooling medium above the storage container outside the portable container,
installing the liquid-phase cooling medium transportation means that transports the liquid-phase cooling medium from the heat radiating apparatus, from the heat radiating apparatus to the heat receiving apparatus, and installing a liquid droplet collecting means that collects a cooling medium liquid droplet that is generated when the gaseous-phase cooling medium transportation means is exposed to atmosphere outside the portable container and the gaseous-phase cooling medium is condensed.

### The Effect of the Invention

According to the present invention, the electronic apparatus cooling system with excellent cooling characteristics and portability can be provided.

### BRIEF DESCRIPTION OF THE DRAWINGS

FIG. 1 is a perspective view which schematically indicates a structure of an electronic apparatus cooling system 100 according to an exemplary embodiment 1.

FIG. 2 is a side view which schematically indicates the structure of the electronic apparatus cooling system 100 according to the exemplary embodiment 1.

FIG. 3 is a front view which indicates a main portion of the electronic apparatus cooling system 100 according to the exemplary embodiment 1.

FIG. 4 is a perspective view which shows a state of a cooling medium inside a vapor phase tube bend 6c.

FIG. 5 is a front view which indicates a main portion of the electronic apparatus cooling system 100 according to an exemplary embodiment 2.

FIG. 6 is a side view which schematically indicates a structure of an electronic apparatus cooling system 200 in which a heat radiating apparatus 4 is housed.

FIG. 7 is a side view which schematically indicates a structure of an electronic apparatus cooling system 300 according to an exemplary embodiment 3.

### EMBODIMENT FOR CARRYING OUT THE INVENTION

Hereinafter, exemplary embodiments of the present invention are described with reference to drawings. The same reference signs are assigned to the same elements in each drawing and repeated descriptions are omitted according to the necessity.

### Exemplary Embodiment 1

First, an electronic apparatus cooling system 100 according to an exemplary embodiment 1 is described. At below, although an electronic apparatus cooling system is constituted so as to be applied to a container type data center, for example, applicable objects are not limited to the container type data center. In addition, as the container size in the container type data center, the container with the size of 20 feet×8 feet×8 feet 6 inches or the half size capacity of 10 feet×8 feet×8 feet 6 inches of ISO (International Standardization Organization) is assumed. However, the size of the container is not limited to those. Moreover, although cases in which the container is employed are described below, it is applicable to not only the container but various vessels with portability and capability to store article therein.

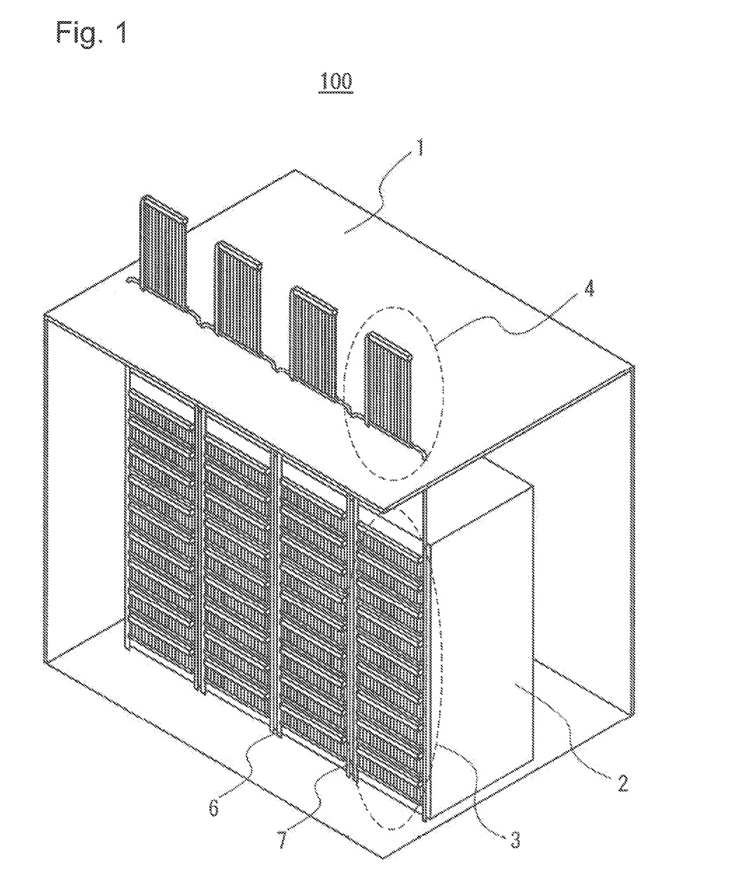

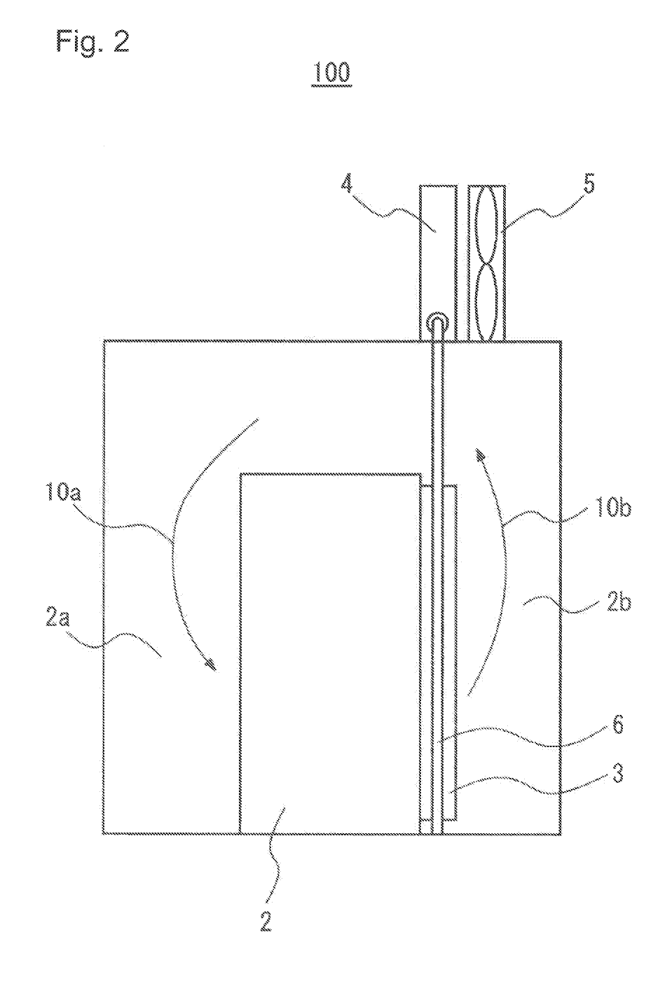

FIG. 1 is a perspective view which schematically indicates a structure of an electronic apparatus cooling system 100 according to the exemplary embodiment 1. Since FIG. 1 is to describe an inside of a container 1, a wall of the front face in FIG. 1 is removed. FIG. 2 is a side view which schematically indicates a structure of the electronic apparatus cooling system 100 according to the exemplary embodiment 1. Since FIG. 2 is to describe the inside of the container 1, a wall of the side in FIG. 1 is removed. The electronic apparatus cooling system 100 has the container 1 and a rack 2.

A server and a network device are equipped into the rack 2 which is a storage container of an electronic apparatus, and it is installed in the approximate center inside the container 1. FIG. 1 indicates an example that four racks 2 are arranged in line as one example. Cooling air 10a for the server and the network device in the container 1 is inhaled from one face side of the rack 2. The air intake side space which is interposed between the container 1 and the rack 2 is called an air intake side space 2a. Warm air 10b which has cooled the server and the network device in the container 1 is discharged outside the container 1 from a face side opposite to the other air intake side of the rack 2. The exhaust side space interposed between the container 1 and the rack 2 is called an exhaust side space 2b.

A rear door (not shown) is installed on a face in the side of the exhaust side space 2b of the rack 2. A heat receiving apparatus 3 which is a heat exchanger is installed on the rear door. Although it is preferable that the heat receiving apparatus 3 is composed of aluminum or copper with excellent thermal conductivity, the material is not limited to those. A heat radiating apparatus 4 which is a heat exchanger is installed on the upper part of the container 1 outside the container 1. Although it is preferable that the heat radiating apparatus 4 is composed of aluminum or copper with excellent thermal conductivity as well as the heat receiving apparatus 3, the material is not limited to those. The heat receiving apparatus 3 and the heat radiating apparatus 4 are connected with each other through a vapor phase tube 6 and a liquid phase tube 7.

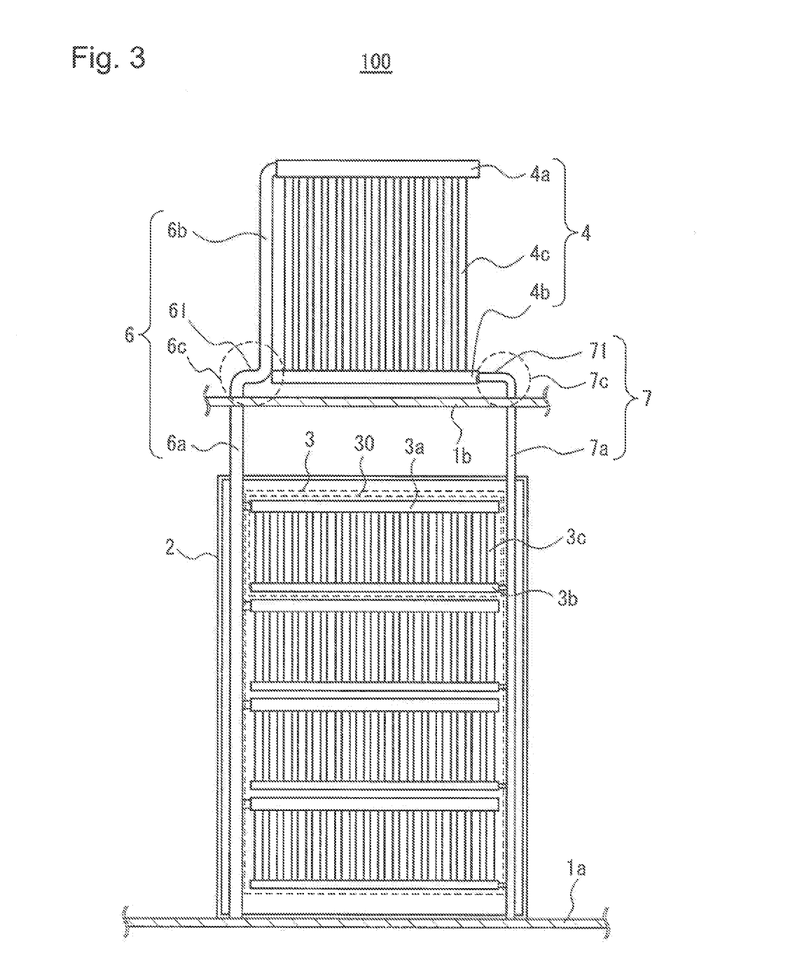

Next, the structures of the heat receiving apparatus 3 and the heat radiating apparatus 4 are described in detail. FIG. 3 is a front view which shows a main portion of the electronic apparatus cooling system 100 according to the exemplary embodiment 1. In FIG. 3, in order to describe the inside of the container 1, a wall of the front face of the container 1 is removed. The heat receiving apparatus 3 has a plurality of heat receiving units 30. The plurality of heat receiving units 30 are arranged in the vertical direction in line on a face of the rear door.

The heat receiving unit 30 includes a header 3a, a header 3b and a tube 3c. The header 3a and the header 3b are paired up. The header 3a is a member which extends in the horizontal direction. The header 3b is a member which extends in the horizontal direction and is installed below the header 3a in the vertical direction. A plurality of tubes 3c which a cooling medium passes though is installed so as to connect the header 3a with the header 3b. Further, in order to cool the cooling medium in the plurality of tubes 3c, a heat radiating fin (not shown) composed of a thin plate member may be installed on the tube 3c.

One end of the header 3a is connected to the vapor phase tube 6 which extends in the vertical direction. The vapor phase tube 6 is a tube which a gaseous-phase cooling medium passes through, and sends the gaseous-phase cooling medium to the heat radiating apparatus 4 mentioned below. In other words, the vapor phase tube 6 has a function to transport a gaseous-phase cooling medium. A tube line through which the gaseous-phase cooling medium passes is installed in the header 3a. The gaseous-phase cooling medium flows into the vapor phase tube 6 through the tube line installed in the header 3a from the tube 3c.

One end of the header 3b is connected to the liquid phase tube 7 which extends in the vertical direction. The liquid phase tube 7 is a tube which the liquid-phase cooling medium passes through, and which the liquid-phase cooling medium flows into from the heat radiating apparatus 4 mentioned below. The tube line which a liquid-phase cooling medium passes through is installed in the header 3b. The liquid-phase cooling medium flows into the tube 3c through the tube line installed in the header 3b from the liquid phase tube 7.

That is, the heat receiving apparatus 3 is implemented as a heat exchanger which cools the rack 2 by vaporizing the liquid-phase cooling medium which has flowed into the tube 3c while the cooling medium flows in the path from the header 3b to the header 3a via the tube 3c. The heat receiving apparatus 3 equally receives heat by using each heat receiving unit 30 and absorbs the exhaust heat of the server and the network device with the inner cooling medium. Thereby, the cooling performance of the whole rack 2 can be improved.

The heat radiating apparatus 4 is composed of a header 4a, a header 4b and a tube 4c. A pair of the header 4a and the header 4b is installed. The header 4a is a member which extends in the horizontal direction. The header 4b is a member which extends in the horizontal direction and is implemented below the header 4a in the vertical direction. The plurality of tubes 4c are tubes which the cooling medium passes through and are installed so as to connect the header 4a with the header 4b. Further, a heat radiating fin (not shown) composed of a thin plate member may be installed on the tube 4c in order to cool the cooling medium in the plurality of tubes 4c.

One end of the header 4a is connected to the vapor phase tube 6 which extends in the vertical direction. The gaseous-phase cooling medium flows into the vapor phase tube 6 from heat receiving apparatus 3. A tube line through which the gaseous-phase cooling medium passes is installed in the header 4a. The liquid-phase cooling medium flows into the tube 4c through the tube line installed in the header 4a from the vapor phase tube 6.

One end of the header 4b is connected to the liquid phase tube 7 which extends in the vertical direction. The liquid phase tube 7 sends the liquid-phase cooling medium to the heat receiving apparatus 3. In other words, the liquid phase tube 7 has a function to transport the liquid-phase cooling medium. A tube line through which the liquid-phase cooling medium passes is installed in the header 4b. The gaseous-phase cooling medium flows into the liquid phase tube 7 through the tube line installed in the header 4b from the tube 4c. That is, the heat radiating apparatus 4 is implemented as a heat exchanger which is cooled and liquefies in the tube 4 while the gaseous-phase cooling medium flows in the path from the header 4a to the header 4b via the tube 4c.

The heat receiving apparatus 3, the heat radiating apparatus 4, the vapor phase tube 6 and the liquid phase tube 7 are implemented so that an insulation cooling medium, for example, flow in the tube line which is sealed. As a cooling medium, although HFC (Hydro Fluoro Carbon) or HFE (Hydro Fluoro Ether), for example, is used, the cooling medium is not limited to those. After the cooling medium is poured into the sealed tube line and decompression by vacuum exhaust is performed, the tube line is sealed up.

The refrigerator 5 which sends cooling air to the heat radiating apparatus 4 is installed on the upper part of the container 1 outside the container 1. For example, a ventilator such as a fan can be used as the refrigerator 5. Further, in FIG. 1, in order to simplify the drawing, the refrigerator 5 is omitted.

Still more, although a metal tube is preferable in order to minimize cooling medium leakage to the outside, the above-mentioned vapor phase tube 6 and liquid phase tube 7 are not limited to that. In addition, in order to run a gaseous-phase cooling medium whose volume is several hundred times of a liquid-phase cooling medium, it is desirable to use a tube line whose diameter is larger than that of the liquid phase tube 7.

The vapor phase tube 6 connects the heat receiving apparatus 3 inside the container 1 with the heat radiating apparatus 4 outside the container 1, as above-mentioned. Here, the vapor phase tube which extends in the vertical direction and is connected to the heat receiving apparatus 3 inside the container 1 is described as a vapor phase tube 6a (referred to as second tube). The vapor phase tube which extends in the vertical direction and is connected to the heat radiating apparatus 4 outside the container 1 is described as a vapor phase tube 6b (referred to as first tube). A vapor phase tube bend 6c is installed between the vapor phase tube 6a and the vapor phase tube 6b. The vapor phase tube bend 6c has a tube line bending in the horizontal direction to the vapor phase tube 6a and the vapor phase tube 6b which extend in the vertical direction. In this example, the vapor phase tube bend 6c is installed outside the container 1.

A liquid phase tube 7 connects the heat receiving apparatus 3 inside the container 1 with the heat radiating apparatus 4 outside the container 1, as mentioned above. Here, the liquid phase tube which extends in the vertical direction and is connected to the heat receiving apparatus 3 inside the container 1 is described as a liquid phase tube 7a (referred to as fourth tube). A liquid phase tube bend 7c is installed between the liquid phase tube 7a and the header 4b. The liquid phase tube bend 7c has a tube line bending in the horizontal direction to the liquid phase tube 7a which extends in the vertical direction. In this example, the liquid phase tube bend 7c is installed outside the container 1.

Next, a cooling operation of the electronic apparatus cooling system 100 is described. The server and the network device installed in the rack 2 of the container 1 inhales cold air from the air intake side space 2a and cools electronic components such as an inner CPU. Warm air which has performed cooling passes the heat receiving apparatus 3 implemented on the rear door, and is discharged into the exhaust side space 2b. In that case, in the heat receiving apparatus 3, the liquid-phase cooling medium is vaporized quickly in the tube 3c and the heat of the warm air is removed by the heat receiving apparatus 3 while the warm air passes through. The air cooled by the heat receiving apparatus 3 circulates inside of the container 1 and is supplied to the air intake side space 2a. In other words, it can be understood that by installing the heat receiving apparatus 3 on the rear door, the heat of the server and the network device is removed without spreading in the container 1.

The cooling medium (gaseous-phase cooling medium) vaporized in the tube 3c of the heat receiving apparatus 3 flows into the heat radiating apparatus 4 through the vapor phase tube 6. The gaseous-phase cooling medium which pours into the heat radiating apparatus 4 passes through the tube 4c of the heat radiating apparatus 4. Since the tube 4c is exposed to cool air outside the container 1, the gaseous-phase cooling medium in the tube 4c is cooled and liquefied (liquid-phase cooling medium). Since the liquid-phase cooling medium density is larger than that of the gaseous-phase cooling medium, the liquid-phase cooling medium descends in the liquid phase tube 7 due to gravity and flows back to the heat receiving apparatus 3. The liquid-phase cooling medium which has flowed back is used for the heat transportation to the heat radiating apparatus 4 by removing the exhaust heat of the server and the network device and vaporizing again. Since the heat which is generated in the server and the network device is removed in the heat receiving apparatus 3 without spreading in the container 1 and is radiated in the outside of the container 1 where open air which is colder than that of the inside thereof exists, high radiation efficiency can be realized.

Furthermore, the cooling medium performs natural circulation between the heat receiving apparatus 3 and the heat radiating apparatus 4 using the density difference between gas and liquid. Therefore, power such as a pump is not needed, space saving of the electronic apparatus cooling system 100 is introduced, and the profitability is obtained from a view of transportation and installation. Moreover, since electric power which is consumed for the cooling medium circulation is not needed, the electric power required for cooling of the rack 2 can be reduced.

In this configuration, since the heat radiating apparatus 4 is exposed in the open air outside the container 1, the vapor phase tube 6b connected to the heat radiating apparatus 4 is also exposed to the open air. Since an open air temperature is lower than the temperature of the vapor phase tube 6b, the gaseous-phase cooling medium tends to condense, and a cooling medium liquid droplet tends to be generated in the vapor phase tube 6b. Since the density of the cooling medium liquid droplet which is generated in the vapor phase tube 6b is larger than that of the gaseous-phase cooling medium, the liquid droplet is drawn due to gravity and descends in the vapor phase tube 6b. In other words, since the liquid droplet descends against flow of the gaseous-phase cooling medium, the situation may occur in which the gaseous-phase cooling medium flow is obstructed and the cooling performance is deteriorated.

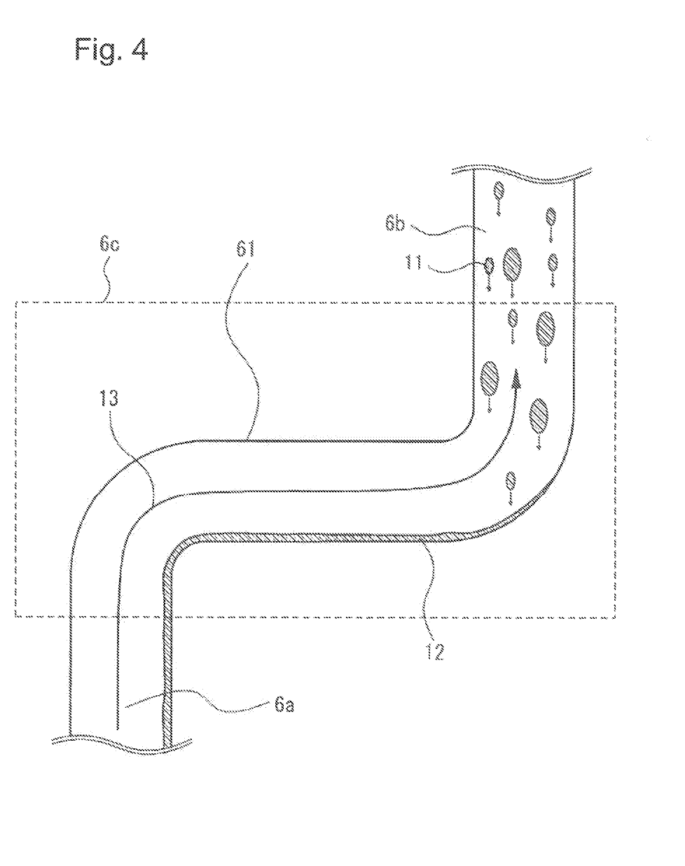

However, in this configuration, the vapor phase tube bend 6c is installed at the part which connects the vapor phase tube 6a with the vapor phase tube 6 outside the container 1. FIG. 4 is a perspective view which shows an aspect of the cooling medium inside the vapor phase tube bend 6c. A cooling medium liquid droplet 11 which has descended is caught on an inner wall of a lower part of a tube line 61 (referred to as third tube) and adheres thereon as a liquid-phase cooling medium 12. The liquid-phase cooling medium 12 which has adhered on the lower inner wall of the tube line 61 flows into the vapor phase tube 6a along the lower inner wall of the tube line 61 which extends in the horizontal direction of the vapor phase tube bend 6c.

The gaseous-phase cooling medium which has flowed into the vapor phase tube 6a descends downwards along the inner wall of the vapor phase tube 6a. Since the vapor phase tube 6a is arranged in the container 1 in which the temperature therein is higher than that of the open air, the cooling medium liquid droplet is difficult to be generated in comparison with the vapor phase tube 6b. In this way, the liquid-phase cooling medium only descends along the inner wall and the flow (reference sign 13 of FIG. 4) of the gaseous-phase cooling medium is not interrupted by the cooling medium liquid droplet in the vapor phase tube 6a. As a result, deterioration of the cooling performance caused by obstructing a flow of the gaseous-phase cooling medium by the cooling medium liquid droplet which is generated in the vapor phase tube which is exposed to the open air can be prevented. In other words, it can be understood that the vapor phase tube bend 6c has a function to collect the cooling medium liquid droplet which is produced inside the vapor phase tube 6b exposed to the open air outside the container 1.

Although the vapor phase tube bend 6c may be provided between the heat receiving apparatus 3 and the heat radiating apparatus 4, it is preferable to put that around a boundary between the container 1 and the open air outside the container 1. Generally, the cooling medium is easy to condense in the vapor phase tube 6 which touches the open air, and the cooling medium is difficult to condense in the vapor phase tube 6 which touches the air which is warmer than the open air in the container 1. Therefore, the cooling medium gets harder to condense by adhering to the wall of the vapor phase tube 6 just before the condensed liquid-phase cooling medium descends to the vapor phase tube 6 in the container 1. As a result, the interruption of the flow of the gaseous-phase cooling medium which goes up in the vapor phase tube 6 in the container 1 can be prevented, and it becomes effective in keeping the cryogenic performance.

### Exemplary Embodiment 2

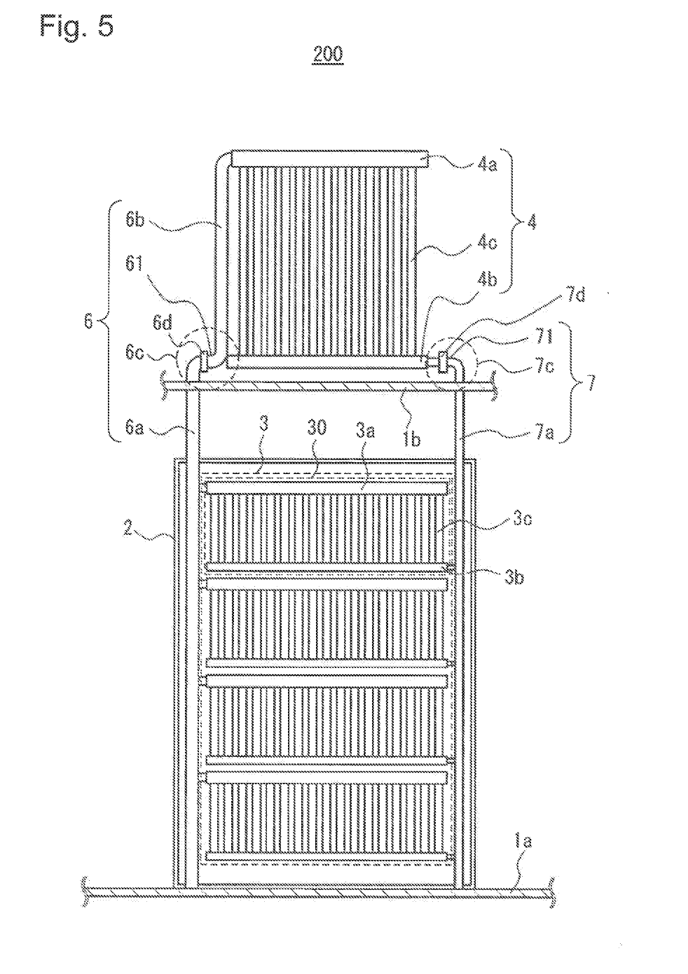

Next, an electronic apparatus cooling system 200 according to an exemplary embodiment 2 is described. The electronic apparatus cooling system 200 is modification of the electronic apparatus cooling system 100 according to the exemplary embodiment 1. FIG. 5 is a front view of a main portion of the electronic apparatus cooling system 200 according to the exemplary embodiment 2. The electronic apparatus cooling system 200 has a configuration in which a movable joint part 6d and a movable joint part 7d are added to the electronic apparatus cooling system 100.

The movable joint part 6d is inserted in the tube line 61 which extends in the horizontal direction in the vapor phase tube bend 6c. The movable joint part 6d is rotatably constituted in the axis direction which is the extension direction of the tube line 61 of the horizontal direction of the vapor phase tube bend 6c. Further, although the movable joint part 6d can employ a joint with a system which can rotate while sealing by using an O-ring or a flexible tube line such as bellows, it is not limited to those.

The movable joint part 7d is inserted in a tube line 71 (referred to as fifth tube) which extends in the horizontal direction of the liquid phase tube bend 7c. The movable joint part 7d is rotatably constituted in the axis direction which is the extension direction of the tube line 71 of the horizontal direction of the liquid phase tube bend 7c, and is coaxial with a rotary shaft of the movable joint part 6d. Further, although the movable joint part 7d can employ a joint with a mechanism that can circulate while shutting using an O-ring or the like, and a flexible tube line such as a bellows, but is not limited to those.

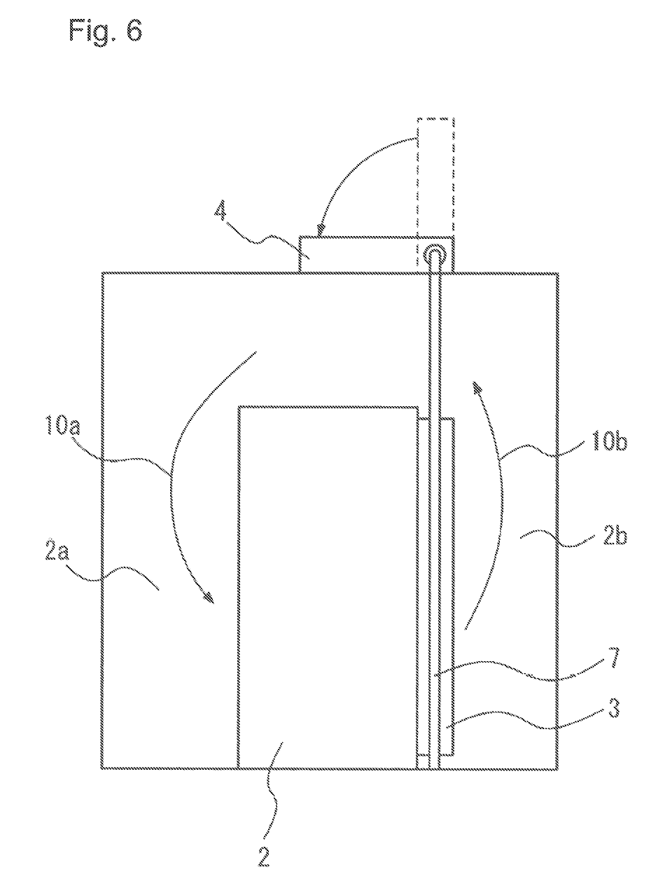

The movable joint part 6d installed in the vapor phase tube bend 6c and the movable joint part 7d installed in the liquid phase tube bend 7c are consisted so as to be coaxial and rotatable. Thereby, the heat radiating apparatus 4 can be folded and stored by laying the apparatus 4 down in parallel to the upper surface of the container 1. FIG. 6 is the side view which schematically indicates a structure of the electronic apparatus cooling system 200 storing the heat radiating apparatus 4. Because it is possible to horizontally store the heat radiating apparatus 4, portability equal to that of a common container can be kept. Further, in FIG. 6, the refrigerator 5 may be installed so as to be stored as well as the heat radiating apparatus 4.

In comparison with this configuration, a condense equipment which cools a cooling medium is exposed to be installed outside an explosion proof container in the Patent Literature 4, for example. Therefore, when the technology described in Patent Literature 4 is applied to the container type data center, a condense equipment is installed outside the container. Accordingly, the condense equipment may be an obstacle when a plurality of containers are kept tightly or the container is transported. Therefore, the portability which is an advantage of the container type data center is spoiled. In contrast, in this configuration, because the heat radiating apparatus 4 can be folded and stored, the problem mentioned above that the technology described in Patent Literature 4 has can be settled.

If the cryogenic performance is considered, it is preferable to vertically erect the heat radiating apparatus 4 to the upper surface of the container 1 so that the center of the header 4a and the center of the header 4b may be lined in the vertical direction. However, when open air temperature of is remarkably low in winter, it is possible to adjust a cooling capacity by inclining the heat radiating apparatus 4 to the upper surface of the container 1 using the movable joint parts 6d and 7d.

Further, in order to fold and store the heat radiating apparatus 4 as mentioned above, it is needed to rotate the heat radiating apparatus 4 with respect to a rotary shaft parallel to the upper surface of the container 1. Therefore, a rolling mechanism whose axis is in the direction parallel to the upper surface of the container 1 is needed. However, in this configuration, the vapor phase tube bend 6c and the liquid phase tube bend 7c each having the tube lines whose axis are in the direction (horizontal direction) parallel to the upper surface of the container 1 are set up to the surface of the container 1. And the movable joint part 6d and the liquid phase tube bend 7c are provided to the tube line in this horizontal direction. Therefore, in comparison with the case in which the vapor phase tube bend and the rolling mechanism are set up separately, this configuration can reduce bending portions and the number of components, realize the manufacturability improvement and reduce a cost.

### Exemplary Embodiment 3

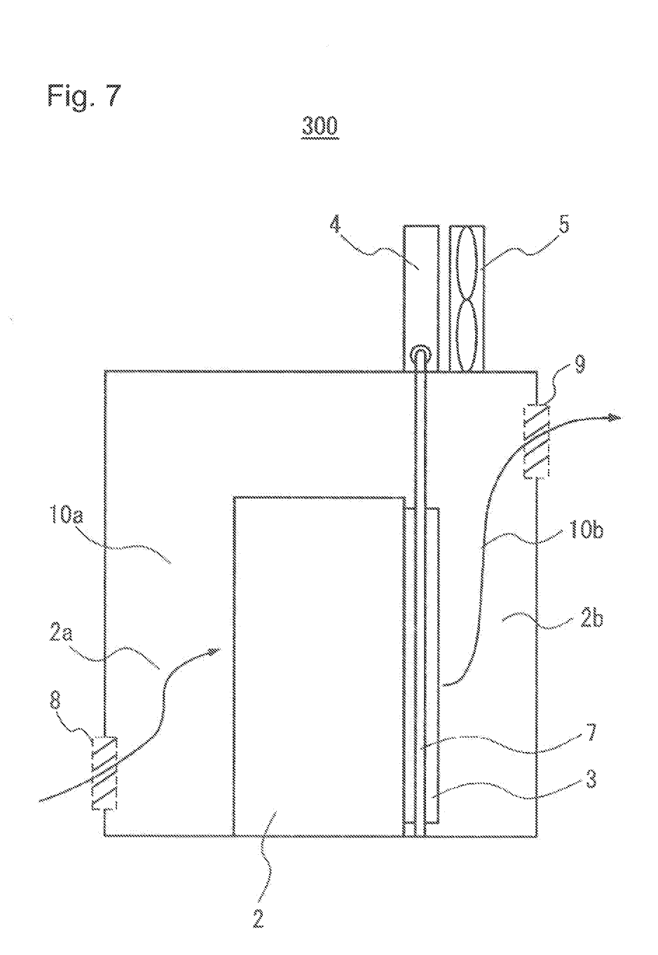

Next, an electronic apparatus cooling system 300 according to an exemplary embodiment 3 is described. The electronic apparatus cooling system 300 is modification of the electronic apparatus cooling system 200 according to the exemplary embodiment 1. FIG. 7 is a side view which schematically indicates a structure of the electronic apparatus cooling system 300 according to the exemplary embodiment 3. The electronic apparatus cooling system 300 has a configuration in which an air intake port 8 and an exhaust port 9 are added on a wall surface of the container 1 of the electronic apparatus cooling system 200. For example, an openable and closable louver can be used as the air intake port 8 and the exhaust port 9.

The air intake port 8 is installed on a wall surface in the side of the air intake side space 2a in the container 1. The open air of the container 1 is introduced in the container 1 through the air intake port 8. The exhaust port 9 is installed on a wall surface in the side of the exhaust side space 2b in the container 1. The air in the container 1 is exhausted to the outside of the container 1 through the exhaust port 9.

Further, it is preferable that the air intake port 8 is installed in the lower part of the wall surface on the side of the air intake side space 2a of the container 1. It is preferable that the exhaust port 9 is installed in the upper part of the wall surface on the side of the exhaust side space 2b of the container 1. An air filter which prevents invasion of such as dust from the container 1 may be installed in the air intake port 8. An insect proof filter which prevents invasion of insects which are fond of warm air may be installed in the exhaust port 9. When the filter is installed in the air intake port 8 and the exhaust port 9, an air intake fan may be installed in the air intake port 8 since pressure loss is increased due to the filter.

When a louver is employed as the air intake port 8 and the exhaust port 9, it can be opened and closed freely by the remote control operation using an electromotive motor. For example, it is possible to prevent the rainwater inflow inside the electronic apparatus cooling system 300 by closing the louver in case of rainfall.

Next, functions of the air intake port 8 and the exhaust port 9 are described. As described in the exemplary embodiment 1, the server and the network device stored in the rack 2 in the container 1 absorb cold air from the air intake side space 2a and cool the electronic parts such as a CPU therein. After cooling, the warm air passes through the heat receiving apparatus 3 provided on the rear door, and is discharged to the exhaust side space 2b. At that time, in the heat receiving apparatus 3, when the warm air passes, the liquid-phase cooling medium in the tube 3c is vaporized quickly, and the heat in the warm air is removed by the heat receiving apparatus 3. The air cooled by the heat receiving apparatus 3 circulates inside of the container 1 and is supplied to the air intake side space 2a. In other words, by providing the heat receiving apparatus 3 on the rear door, the heat of the server and the network device is removed without spreading in the container 1.

However, it is difficult to completely remove the heat of the warm air discharged from the rear door in the heat receiving apparatus 3, and the warm air which has higher temperature compared with that of the air intake side space 2a is discharged in the exhaust side space 2b. The warm air which cannot be removed in the heat receiving apparatus 3 goes up due to density difference and is discharged naturally from the exhaust port 9. The open air which is colder than that inside the container 1 is inhaled from the air intake port 8 by only the same volume as the warm air discharged from the exhaust port 9. Thereby, the air flow caused by natural circulation using the air intake port 8 and the exhaust port 9 can be secured inside the container 1. In this way, it is possible to cool not only the inside of the rack 2, but also the inside of the container 1, and the cryogenic performance can be further improved.

Since an outer wall of the container 1 is generally made of a metal plate thinner than an outer wall of a building, the air intake port 8 and the exhaust port 9 can be installed more easily than the outer wall of a building. Moreover, because the air intake port 8 and the exhaust port 9 can be installed in a container outer wall, there is no need to prepare an exclusive installation space separately, and the excellent portability of the electronic apparatus cooling system can be maintained.

Further, the present invention is not limited to the exemplary embodiments mentioned above, and it can be changed appropriately in the range that does not deviate from the gist. For example, the air intake port 8 and the exhaust port 9 can be added to the electronic apparatus cooling system 100.

According to the exemplary embodiments mentioned above, although a case in which one vapor phase tube bend 6c is installed to the vapor phase tube 6 is described, this is only one example. Therefore, a plurality of vapor phase tube bends 6c may be set up to the vapor phase tube 6. Although a case in which one liquid phase tube bend 7c is set up to the liquid phase tube 7 is described, this is only one example. Therefore, a plurality of liquid phase tube bends 7c may be set up to the liquid phase tube 7.

According to the exemplary embodiments mentioned above, although a case in which four racks 2 are installed in the container 1 is described, this is only one example. The optional number of the racks 2 may be installed in the container 1 in the range of capacity of the container.

The above-mentioned electronic apparatus cooling system can be applied to not only the cooling of the data center but also the cooling of other systems that include an electronic apparatus.

This application is based upon and claims the benefit of priority from Japanese patent application No. 2013-035455, filed on Feb. 26, 2013, the disclosure of which is incorporated herein in its entirety by reference.

Although it can also be described in the following addition, the part or the entire embodiment mentioned above is not limited to below.

[Supplementary Note 1]

An electronic apparatus cooling system, comprising a portable container with a space that can store an article therein, a storage container that installs an electronic apparatus that is installed inside the portable container, a heat receiving apparatus that is installed on a side of the storage container and receives heat that is generated inside the storage container as a liquid-phase cooling medium is evaporated to become a gaseous-phase cooling medium, a gaseous-phase cooling medium transportation means that is installed so as to extend in the vertical direction and transports the gaseous-phase cooling medium from the heat receiving apparatus, a heat radiating apparatus that is installed above the storage container outside the portable container and radiates the heat that the heat receiving apparatus receives by cooling the gaseous-phase cooling medium that flows into from the gaseous-phase cooling medium transportation means to make the liquid-phase cooling medium, and a liquid-phase cooling medium transportation means that transports the liquid-phase cooling medium from the heat radiating apparatus to the heat receiving apparatus, wherein the gaseous-phase cooling medium transportation means comprises a liquid droplet collecting means that collects a cooling medium liquid droplet that is generated when the gaseous-phase cooling medium transportation means is exposed to atmosphere outside the portable container and the gaseous-phase cooling medium is condensed.

[Supplementary Note 2]

The electronic apparatus cooling system according to the supplementary note 1, wherein the gaseous-phase cooling medium transportation means further comprises,

a first tube that extends in the vertical direction outside the portable container and is connected to the heat radiating apparatus, and a second tube that extends in the vertical direction inside the portable container and is connected to the heat receiving apparatus, wherein the liquid droplet collecting means is inserted between the first tube and the second tube.

[Supplementary Note 3]

The electronic apparatus cooling system according to the supplementary note 2, wherein the liquid droplet collecting means further comprises a third tube that extends in the direction crossing at right angles with the vertical direction and is installed, and whose one end is connected to the bottom end of the first tube and whose other end is connected to the second tube, and

the cooling-medium liquid droplet that falls down through the first tube is caught at an inner wall of the lower side of the third tube.

### [Supplementary Note 4]

The electronic apparatus cooling system according to the supplementary note 3, wherein the third tube is installed outside the portable container.

[Supplementary Note 5]

The electronic apparatus cooling system according to the supplementary note 4, wherein the liquid-phase cooling medium transportation means comprises, a fourth tube that extends in the vertical direction inside the portable container and is connected to the heat receiving apparatus, and a fifth tube whose one end is connected to the upper end of the fourth tube and whose other end is connected to the heat radiating apparatus outside the portable container, wherein the third tube and the fifth tube are arranged in a coaxial position.

[Supplementary Note 6]

The electronic apparatus cooling system according to the supplementary note 5, wherein the heat radiating apparatus is rotatably constituted around a center axis of the third tube and the fifth tube as a rotary shaft.

[Supplementary Note 7]

The electronic apparatus cooling system according to the supplementary note 6, wherein the gaseous-phase cooling medium transportation means is inserted in the third tube and further comprises a first moving part that is constituted so as to rotate the third tube of the heat radiating apparatus side around the center axis, and the liquid-phase cooling medium transportation means is inserted in the fifth tube and further comprises a second moving part that is constituted so as to rotate the fifth tube of the heat radiating apparatus side around the center axis.

[Supplementary Note 8]

The electronic apparatus cooling system according to any one of the supplementary notes 1 to 7, further comprising an intake port that is installed on a side of the portable container and takes air in from the outside of the portable container, and an exhaust port that is installed on the side of the portable container and discharges air to the outside the portable container.

[Supplementary Note 9]

The electronic apparatus cooling system according to the supplementary note 8, wherein the intake port is installed on a wall of the portable container on the side where the storage container takes air therein, and the exhaust port is installed on a wall of the portable container on the side where the storage container discharges air therefrom.

[Supplementary Note 10]

The electronic apparatus cooling system according to supplementary note 8 or 9, wherein the intake port is installed below the exhaust port in the vertical direction.

[Supplementary Note 11]

An electronic apparatus cooling system fabrication method, comprising installing a storage container having an electronic apparatus therein inside a portable container whose internal space is sealable, installing a heat receiving apparatus that receives heat that is generated inside the storage container as a liquid-phase cooling medium is evaporated to become a gaseous-phase cooling medium, on a side of the storage container,

installing a gaseous-phase cooling medium transportation means that transports the gaseous-phase cooling medium from the heat receiving apparatus so as to extend in the vertical direction, installing a heat radiating apparatus radiating the heat which the heat receiving apparatus receives by cooling the gaseous-phase cooling medium that flows in from the gaseous-phase cooling medium transportation means so as to generate the liquid-phase cooling medium above the storage container outside the portable container, installing the liquid-phase cooling medium transportation means that transports the liquid-phase cooling medium from the heat radiating apparatus, from the heat radiating apparatus to the heat receiving apparatus, and installing a liquid droplet collecting means that collects a cooling medium liquid droplet that is generated when the gaseous-phase cooling medium transportation means is exposed to atmosphere outside the portable container and the gaseous-phase cooling medium is condensed.

### REFERENCE SIGNS LIST

1 Container.

2 Rack.

2a Air intake side space.

2b Exhaust side space.

3 Heat receiving apparatus.

3a, 3b, 4a and 4b Header

3c and 4c Tube

4 Heat radiating apparatus.

5 Refrigerator.

6, 6a and 6b Vapor phase tube.

6c Vapor phase tube bend.

6d Movable joint part.

7 and 7a Liquid phase tube.

7c Liquid phase tube bend.

7d Movable joint part.

8 Air intake port.

9 exhaust port.

11 Cooling medium liquid droplet.

12 Liquid-phase cooling medium.

13 Gaseous-phase cooling medium flow.

30 Heat receiving unit.

61 and 71 Tube line.

100 or 200 and 300 Electronic apparatus cooling system.

1. An electronic apparatus cooling system, comprising:
a container with a space that can store an article therein;
a storage container that comprises an electronic apparatus that is installed inside the container;
a heat receiving apparatus that is installed on a side of the storage container and receives heat that is generated inside the storage container as a liquid-phase cooling medium is evaporated to become a gaseous-phase cooling medium;
a gaseous-phase cooling medium transporter that transports the gaseous-phase cooling medium from the heat receiving apparatus;
a heat radiating apparatus that is installed above the storage container outside the container, and radiates the heat that the heat receiving apparatus receives by cooling the gaseous-phase cooling medium that flows into from the gaseous-phase cooling medium transporter to make the liquid-phase cooling medium; and
a liquid-phase cooling medium transporter that transports the liquid-phase cooling medium from the heat radiating apparatus to the heat receiving apparatus, wherein
the gaseous-phase cooling medium transporter comprises a liquid droplet collector that collects a cooling medium liquid droplet in the gaseous-phase cooling medium transporter.

2. The electronic apparatus cooling system according to claim 1, wherein
the gaseous-phase cooling medium transporter further comprises:
a first tube that extends in the vertical direction outside the container and is connected to the heat radiating apparatus; and
a second tube that extends in the vertical direction inside the container and is connected to the heat receiving apparatus, wherein
the liquid droplet collector is inserted between the first tube and the second tube.

3. The electronic apparatus cooling system according to claim 2, wherein
the liquid droplet collector further comprises a third tube that extends in the direction crossing at right angles with the vertical direction and is installed, and whose one end is connected to the bottom end of the first tube and whose other end is connected to the second tube, and
the cooling-medium liquid droplet that falls down through the first tube is caught on an inner wall of the lower side of the third tube.

4. The electronic apparatus cooling system according to claim 3, wherein
the third tube is installed outside the container.

5. The electronic apparatus cooling system according to claim 4, wherein
the liquid-phase cooling medium transporter comprises:
a fourth tube that extends in the vertical direction inside the container and is connected to the heat receiving apparatus; and
a fifth tube whose one end is connected to the upper end of the fourth tube and whose other end is connected to the heat radiating apparatus outside the container, wherein
the third tube and the fifth tube are arranged in a coaxial position.

6. The electronic apparatus cooling system according to claim 5, wherein
the heat radiating apparatus is rotatably constituted so as to rotate around a center axis of the third tube and the fifth tube as a rotary shaft.

7. The electronic apparatus cooling system according to claim 6, wherein
the gaseous-phase cooling medium transporter is inserted in the third tube and further comprises a first moving part that is constituted so as to rotate the third tube of the heat radiating apparatus side around the center axis, and
the liquid-phase cooling medium transporter is inserted in the fifth tube and further comprises a second moving part that is constituted so as to rotate the fifth tube of the heat radiating apparatus side around the center axis.

8. The electronic apparatus cooling system according to claim 1, further comprising:
an intake port that is installed on a side of the container and takes air in from the outside of the container; and
an exhaust port that is installed on the side of the container and discharges air to the outside the container.

9. The electronic apparatus cooling system according to claim 8, wherein
the intake port is installed on a wall of the container on the side where the storage container takes air therein, and
the exhaust port is installed on a wall of the container on the side where the storage container discharges air therefrom.

10. The electronic apparatus cooling system according to claim 8, wherein
the intake port is installed below the exhaust port in the vertical direction.

11. An electronic apparatus cooling system fabrication method, comprising:
installing a storage container having an electronic apparatus inside a container whose internal space is sealable;
installing a heat receiving apparatus that receives heat that is generated inside the storage container as a liquid-phase cooling medium is evaporated to become a gaseous-phase cooling medium, on a side of the storage container;
installing a gaseous-phase cooling medium transporter that transports the gaseous-phase cooling medium from the heat receiving apparatus;
installing a heat radiating apparatus radiating the heat which the heat receiving apparatus receives by cooling the gaseous-phase cooling medium that flows in from the gaseous-phase cooling medium transporter so as to generate the liquid-phase cooling medium above the storage container outside the container;
installing the liquid-phase cooling medium transporter that transports the liquid-phase cooling medium from the heat radiating apparatus, from the heat radiating apparatus to the heat receiving apparatus; and
installing a liquid droplet collector that collects a cooling medium liquid droplet in the gaseous-phase cooling medium transporter.

12. The electronic apparatus cooling system according to claim 1, wherein the liquid droplet collector collects a cooling medium liquid droplet that is generated when the gaseous-phase cooling medium transporter is exposed to atmosphere outside the container and the gaseous-phase cooling medium is condensed.

13. The electronic apparatus cooling system according to claim 1, wherein the gaseous-phase cooling medium transporter is installed so as to extend in the vertical direction.

14. The electronic apparatus cooling system according to claim 1, wherein the container has portability.

15. The electronic apparatus cooling system according to claim 1, wherein the heat radiating apparatus radiates heat that the heat receiving apparatus receives to open air.
